(19) United States
(12) Patent Application Publication
(10) Pub. No.: US 2022/0104377 A1
(43) Pub. Date: Mar. 31, 2022

(54) ENCLOSURE FOR ELECTRONIC ASSEMBLIES EXPOSED TO INCLEMENT WEATHER CONDITIONS

(71) Applicant: iTronics Co., Ltd., Hong Kong (CN)

(72) Inventor: Jun Hu, Hong Kong (CN)

(73) Assignee: iTronics Co., Ltd., Hong Kong (CN)

(21) Appl. No.: 17/033,397

(22) Filed: Sep. 25, 2020

(51) Int. Cl. H05K 5/06; G01W 1/02

(52) U.S. Cl. CPC H05K 5/061; G01W 1/02

(57) ABSTRACT

An electronic weather instrument for use in severe, inclement weather conditions is disclosed. To protect sensitive electronic circuitry against adverse weather conditions, a specialize housing is provided. Delicate and/or moisture sensitive circuitry is contained in a chamber in the housing that is sealed against moisture and sealed from the ambient atmosphere. However, to enable the weather instrument to react quickly and accurately to temperature and/or humidity changes and the like, sensors for sensing such weather parameters are contained within another chamber of the housing that is not sealed as tightly as the sealed chamber and that communicates directly with the ambient atmosphere. This provides an effective weather instrument that responds quickly and accurately to atmospheric conditions while shielding sensitive or otherwise delicate circuitry from moisture and other inclement conditions to improve reliability and life of the device.

### FIELD OF THE INVENTION

The invention relates to electronic assemblies and more particularly to enclosures for electronic circuits, systems and assemblies that are, or may be subjected to, inclement weather conditions.

### BACKGROUND

Through the years, instruments, such as thermometers and barometers, for sensing weather conditions, such as temperature and barometric pressure, have evolved from the mechanical to the electronic. Although modern electronic circuitry and techniques offer tremendous advantages over purely mechanical approaches, a basic problem is that electronic circuits, components and devices themselves are not inherently weatherproof and, to ensure reliability, must themselves be shielded from rain, snow, ice, etc. Accordingly, a variety of enclosures have been developed over the years to permit the installation of electronic weather devices where they are exposed to sometimes extreme weather conditions.

One approach to protecting electronic circuits and devices from direct exposure to rain, humidity and other adverse weather conditions is to encase the circuitry in an enclosure that is, itself, weatherproof and sealed to prevent water and humidity from reaching delicate and/or sensitive electronic components. Although effective in shielding sensitive circuitry from the elements, providing too effective isolation of the circuitry from the weather can interfere with the ability of the circuitry to quickly ascertain, and accurately sense, current weather parameters.

Accordingly, there is a heretofore unmet need in the art for practical, economical ways of protecting weather sensing instrument electronics from harsh weather conditions while not interfering with the ability of the instrument to sense actual weather conditions quickly and accurately.

### SUMMARY OF THE INVENTION

The invention is directed to apparatus, methods and techniques for protecting sensitive electronic circuitry, devices and systems from inclement weather conditions while not significantly interfering with the ability of such circuitry, devices and systems to sense, accurately and quickly, true weather conditions. The invention is also directed to housings and enclosures for weather sensing electronic circuitry, devices and systems to protect them from inclement weather conditions while not significantly interfering with their ability to sense, accurately and quickly, true weather conditions. The invention is also directed to housings and enclosures for weather sensing electronic circuitry, devices and systems to protect them from inclement weather conditions, that can be easily and inexpensively manufactured for use in mass-marketed, inexpensive consumer weather-measurement devices.

In one embodiment, the housing includes two chambers, one of which is an isolated chamber that is exposed to the ambient atmosphere and the other of which is separated from the isolated chamber by a chamber wall and sealed from the ambient atmosphere. By placing the weather sensing elements in the isolated chamber, they can respond quickly to changes in weather conditions. The remaining circuitry can be contained in the other, sealed chamber where it is protected from moisture and other harsh weather conditions. A wire passing through the chamber wall and sealed to the chamber wall interconnects the weather sensing elements with the remaining circuitry while maintaining physical and atmospheric separation of the two chambers.

These and other features and advantages will be apparent from a reading of the following detailed description and a review of the associated drawings. It is to be understood that both the foregoing general description and the following detailed description are explanatory only and are not restrictive. Among other things, the various embodiments described herein may be embodied as methods, devices, or a combination thereof. The disclosure herein is, therefore, not to be taken in a limiting sense.

### BRIEF DESCRIPTION OF THE FIGURES

The features of the present invention that are believed to be novel are set forth with particularity in the appended claims. The invention, together with the further objects and advantages thereof, may best be understood by reference to the following description taken in conjunction with the accompanying drawings, wherein like reference numerals identify like elements and wherein:

FIG. 1 is an isometric view of one embodiment of an enclosure for electronic assemblies exposed to inclement weather conditions constructed in accordance with various aspects of the invention.

FIG. 2 is an exploded view of the enclosure shown in FIG. 1 illustrating the construction and configuration thereof.

### DETAILED DESCRIPTION

Various embodiments will be described in detail with reference to the drawings, wherein like reference numerals represent like parts and assemblies throughout the several views. Many details of certain embodiments of the disclosure are set forth in the following description and accompanying figures so as to provide a thorough understanding of the embodiments. Reference to various embodiments does not limit the scope of the claims attached hereto. Additionally, any examples set forth in this specification are not intended to be limiting and merely set forth some of the many possible embodiments for the appended claims.

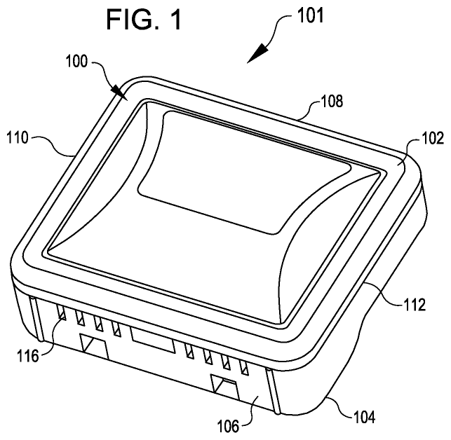

With reference to FIG. 1, an enclosure 100 for electronic assemblies constructed in accordance with one aspect of the invention is shown. As illustrated, the enclosure 100 is intended for use in connection with an electronic thermometer and/or hygrometer 101 for outdoor use in extreme weather conditions wherein rain, snow and other moisture is present and temperatures can range as low as −30 Degrees Celsius (−22 Fahrenheit). The housing is of generally rectangular form having an upper surface 102, a lower surface 104, a pair of opposed front and back walls or surfaces 106, 108 and a pair of opposed left and right side walls or surfaces 110, 112. While in the illustrated embodiment, the enclosure 100 is part of a battery-operated, outdoor weather monitoring instrument 101 for sensing and displaying sensed weather data, such as temperature and/or relative humidity, it will be appreciated that the housing can be used with other devices and instruments as well.

As illustrated, the front surface 106 of the enclosure includes a plurality of venting holes 116, which in the illustrated embodiment, consist of a number of rectangularly shaped vertical slots extending through the front surface 106.

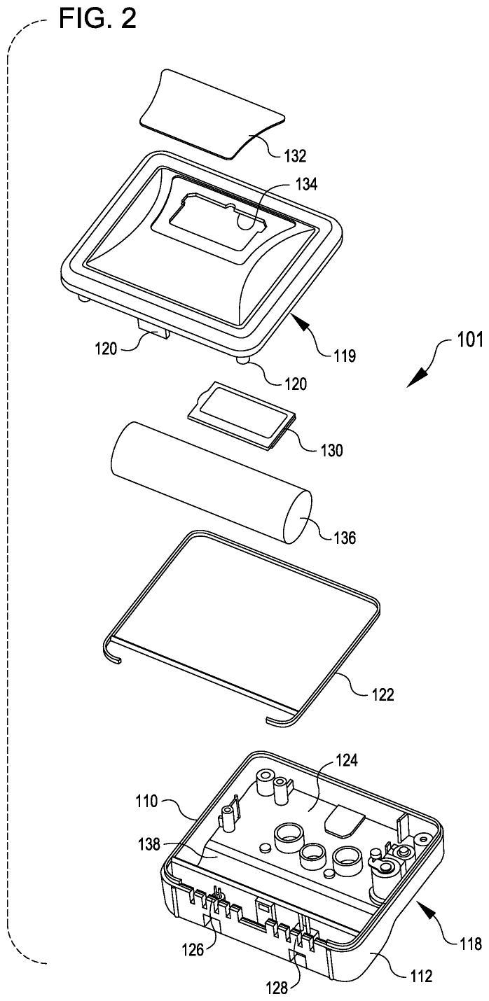

The construction and interior configuration of the enclosure 100 is best seen in FIG. 2. As illustrated, the lower surface 104, the front and back surfaces 106, 108, and the opposed left and right side surfaces 110 and 112 are preferably integrally formed as a single, lower unit 118, while the upper surface 102 is preferably formed as a separate upper unit 119 that is installed over the lower unit to form a fully enclosed housing. Preferably, the upper unit 119 includes a plurality of flexible tabs 120 that fit into receptive slots formed in the lower unit 118 to enable the upper unit to be “snapped” into place to form a unitary structure.

As further illustrated, a seal or gasket 122, which in the illustrated embodiment consists of a silicone polymer O-ring, is provided between the lower unit 118 and the upper unit 119 to provide a weather-resistant seal between the two when they are assembled to each other.

As further illustrated in FIG. 2, a main circuit board 124 is contained within the lower unit 118 between the lower unit 118 and the upper unit 119. In addition, one or more weather parameter sensors, such as a temperature detector 126 and a relative humidity detector 128, are provided in the lower unit 118 to sense these respective weather parameters. The detectors 126 and 128 are electronically coupled via wires to the main circuit board 124, which, in turn, contains circuitry for processing signals sensed by the detectors to convert them into a human-readable form.

A display 130, preferably in the form of a liquid crystal display, is provided to display the sensed temperature and/or relative humidity and is disposed above the main circuit board 124 under the upper unit 119. Preferably, a transparent window 132 is provided in the upper unit 119 over an aperture 134 formed therein to permit the display to be seen from outside of the enclosure 100. Power for energizing the detectors 126, 128, the main circuit board 124 and the display 130 is provided by means of a battery 136, that is also contained in the housing 100, between the lower unit 118 and the upper unit 119. Preferably, the battery 136 is a rechargeable lithium battery. Alternatively, replaceable or non-rechargeable lithium or non-lithium batteries can be used.

Preferably, the lower unit 118 and upper unit 119 are each formed of a durable, rigid, injection-molded plastic such as [here list all possibilities]. As previously noted, the seal or gasket 122 is preferably formed of a silicone polymer, while the window 132 is formed of a durable, weather-resistant transparent plastic.

In accordance with one aspect of the invention, the housing is configured to have basically two isolated interior chambers that, in the illustrated embodiment are defined by an internal chamber wall or baffle 138 formed inside the lower unit 118 and extending between the side walls 110, 112 parallel and spaced from the front and back walls 106, 108. In the illustrated embodiment, the chamber wall or baffle 138 is positioned near and spaced from the front wall 106 by a sufficient distance to provide room for the detectors 126, 128, which, in turn, are positioned in the space between the baffle 138 and the front wall 106. By so positioning the detectors 126, 128, the detectors are able quickly to sense the temperature and relative humidity of the ambient air, which is able to reach the detectors through the venting holes 116 formed in the front wall 106. In addition, by so positioning the detectors 126, 128, the detectors remain largely protected from rain, snow, hail and other weather conditions while remaining in intimate contact with the ambient atmosphere. It will be appreciated that, in actual use, the weather device will likely be mounted so that the front wall 106 faces downwardly toward the surface of the Earth, with the front surface 102 and side walls 110, 112 oriented vertically.

In accordance with one aspect of the invention, the main circuit board 124 is located on the other side of the baffle or chamber wall 138 opposite the detectors 126,128. Electrical communication between the main circuit board 124 and the detectors 126, 128 is provided by means of wires or conductors extending between the two and that pass through the chamber wall 138 in sealed engagement therewith. In one embodiment, the conductors pass through small slots or holes in the chamber wall 138 and are then sealed by means of a silicone polymer to ensure a water-tight and weatherproof between the conductors and wall 138. By so positioning the detectors 126, 128 and the main circuit board 124 relative to the chamber wall 138 and interior chambers of the housing, the main circuit board 124, along with the display 130 and the battery 136, can be fully protected from moisture and other adverse conditions, while the detectors 126, 128 can remain in intimate contact with the ambient air to provide rapid sensing and responses to changing atmospheric conditions. This allows the apparatus to sense, rapidly and accurately, actual weather conditions, while keeping sensitive and fragile electronic circuitry safely protected from moisture and other potentially damaging conditions.

Those skilled in the art will recognize that, in its broader aspects, the invention is not limited to the particular form illustrated. For example, the shape of the housing 100 can be modified to accommodate the particular form of instrument to be provided, and the weather parameters to be monitored are not limited only to temperature and/or relative humidity. The particular materials used are not critical provided they are sufficiently rigid, weatherproof and durable to protect the circuitry contained therein. Furthermore, the size, shape and configuration of the interior compartments of the housing are not critical, provided the weather-sensing devices are exposed to the actual ambient atmosphere while the sensitive components are safely contained in a separate compartment isolated from moisture and/or other potentially damaging conditions.

While a particular embodiment of the invention has been shown and described, it will be apparent to those skilled in the art that changes and modifications can be made without departing from the invention in its broader aspects, and, therefore, the aim in the appended claims is to cover all such changes and modifications as fall within the true spirit and scope of the invention.

1. An enclosure for electronic circuitry, which circuitry includes a sensing element for sensing a parameter of the ambient atmosphere and additional circuitry for processing information from the sensing element, said enclosure comprising:
a housing defining two interior chambers;
wherein the first of the interior chambers is sized and dimensioned to house the sensing element and includes one or more apertures open to the ambient atmosphere; and
wherein the second of the interior chambers is sealed to the ambient atmosphere and is sized and dimensioned to house the additional circuitry for processing information from the sensing element.

2. An enclosure as defined in claim 1 wherein the housing includes a lower unit defining the two interior chambers and an upper unit attachable to the lower unit to further define the two interior chambers.

3. An enclosure as defined in claim 2 wherein the upper unit is sealed to the lower unit to prevent the passage of moisture between the upper unit and the lower unit.

4. An enclosure as defined in claim 3 further including a seal between the upper unit and the lower unit.

5. An enclosure as defined in claim 4 wherein the upper unit and the lower unit are formed of a molded plastic.

6. An enclosure as defined in claim 5 wherein the seal is formed of a silicon polymer.

7. An enclosure as defined in claim 6 wherein one of the sensing elements is a temperature sensor.

8. An enclosure as defined in claim 7 wherein the other of the sensing elements is a humidity sensor.

9. An enclosure as defined in claim 2 wherein the upper unit includes a transparent window to permit observation of at least a portion of the interior of the second interior chamber.

10. An enclosure as defined in claim 9 wherein the second of the interior chambers is sized and dimensioned to include an energy source.

11. An enclosure as defined in claim 10 wherein the energy source is a rechargeable battery.

12. An enclosure as defined in claim 9 wherein the energy source is non-rechargeable battery.

13. A whether instrument for sensing outdoor whether parameters comprising;
a sensing element for sensing a parameter of the ambient atmosphere;
circuitry coupled to said sensing element for providing a visual display of the parameter sensed by the sensing element;
a housing defining first and second interior chambers;
wherein the first of the interior chambers is sized and dimensioned to house the sensing element and includes one or more apertures open to the ambient atmosphere; and
wherein the second of the interior chambers is substantially sealed to the ambient atmosphere and is sized and dimensioned to house the additional circuitry for processing information from the sensing element.

14. A whether instrument as defined in claim 13 wherein the sensing element is a temperature sensor for sensing the temperature of the ambient atmosphere.

15. A whether instrument as defined in claim 13 wherein the sensing element is a humidity sensor for sensing the relative humidity of the ambient atmosphere.

16. A whether instrument as defined in claim 14 further including an additional sensing element for sensing the relative humidity of the ambient atmosphere in addition to the temperature of the ambient atmosphere.

17. A whether instrument as defined in claim 16 further including an energy source contained within the second interior chamber.

18. A whether instrument as defined in claim 17 wherein the energy source is a rechargeable battery.

19. A whether instrument as defined in claim 17 wherein the energy source is a non-rechargeable battery.

20. A whether instrument as defined in claim 13 wherein the housing includes a lower unit defining in part the first and second interior chambers and an upper unit overlying the lower unit to define the remainder of the first and second interior chambers.
